(19) United States
(12) Patent Application Publication
(10) Pub. No.: US 2020/0075652 A1
(43) Pub. Date: Mar. 5, 2020

(54) PIXEL CELL WITH MULTIPLE PHOTODIODES

(71) Applicant: Facebook Technologies, LLC, Menlo Park, CA (US)

(72) Inventors: Song CHEN, Redmond, WA (US); Xinqiao LIU, Medina, WA (US)

(21) Appl. No.: 16/560,665

(22) Filed: Sep. 4, 2019

Related U.S. Application Data
(60) Provisional application No. 62/727,343, filed on Sep. 5, 2018.

(51) Int. Cl. H01L 27/146; G06F 3/01

(52) U.S. Cl. CPC H01L 27/14621; H01L 27/14627; H01L 27/14649; H04N 13/254; H01L 27/1463; H01L 27/1464; G06F 3/012; H01L 27/14645

(57) ABSTRACT

In one example, an apparatus comprises: a semiconductor substrate including a plurality of pixel cells, each pixel cell including at least four photodiodes; a plurality of filter arrays, each filter array including a filter element overlaid on each photodiode of the pixel cell, at least two of the filter elements of the each filter array having different wavelength passbands; and a plurality of microlens, each microlens overlaid on the each filter array and configured to direct light from a spot of a scene via each filter element of the each filter array to each photodiode of the each pixel cell.

### RELATED APPLICATIONS

This patent application claims priority to U.S. Provisional Patent Application Ser. No. 62/727,343, filed Sep. 5, 2018, entitled “PIXEL STRUCTURE WITH REDUCED CROSSTALK BETWEEN MULTIPLE PHOTODIODES,” which is assigned to the assignee hereof and is incorporated herein by reference in its entirety for all purposes.

### BACKGROUND

The disclosure relates generally to image sensors, and more specifically to a pixel cell that includes multiple photodiodes.

A typical pixel cell in an image sensor includes a photodiode to sense incident light by converting photons into charge (e.g., electrons or holes). The charge can be temporarily stored in photodiode during an exposure period. For improved noise and dark current performances, a pinned photodiode can be included in the pixel to convert the photons into charge. The pixel cell may further include a capacitor (e.g., a floating diffusion) to collect the charge from the photodiode and to convert the charge to a voltage. An image sensor typically includes an array of pixel cells. The pixel cells can be configured to detect light of different wavelength ranges to generate 2D and/or 3D image data.

### SUMMARY

The present disclosure relates to image sensors. More specifically, and without limitation, this disclosure relates to a pixel cell configured to perform collocated sensing of light of different wavelengths.

In one example, an apparatus is provided. The apparatus includes a semiconductor substrate including a plurality of pixel cells, each pixel cell including at least a first photodiode, a second photodiode, a third photodiode, and a fourth photodiode. The apparatus further includes a plurality of filter arrays, each filter array including at least a first filter element, a second filter element, a third filter element, and a fourth filter element, the first filter element of the each filter array overlaid on the first photodiode of the each pixel cell, the second filter element of the filter array overlaid on the second photodiode of the each pixel cell, the third filter element of the filter array overlaid on the third photodiode of the each pixel cell, the fourth filter element of the filter array overlaid on the fourth photodiode of the each pixel cell, at least two of the first, second, third, and fourth filter element of the each filter array having different wavelength passbands. The apparatus further includes a plurality of microlens, each microlens overlaid on the each filter array and configured to direct light from a spot of a scene via the first filter element, the second filter element, the third filter element, and the fourth filter element of the each filter array to, respectively, the first photodiode, the second photodiode, the third photodiode, and the fourth photodiode of the each pixel cell.

In one aspect, the first filter element and the second filter element of the each filter array are aligned along a first axis. The first photodiode and the second photodiode of the each pixel cell are aligned along the first axis underneath a light receiving surface of the semiconductor substrate. The first filter element is overlaid on the first photodiode along a second axis perpendicular to the first axis. The second filter element is overlaid on the second photodiode along the second axis. The each microlens is overlaid on the first filter element and the second filter element of the each filter array along the second axis.

In one aspect, the apparatus further comprises a camera lens overlaid on the plurality of microlenses along the second axis. A surface of the each filter array facing the camera lens and an exit pupil of the camera lens are positioned at conjugate positions of the each microlens.

In one aspect, the first filter element and the second filter element overlaid on the each pixel cell are configured to pass different color components of visible light to, respectively, the first photodiode and the second photodiode of the each pixel cell.

In one aspect, the first filter element and the second filter element of each filter array are arranged based on a Bayer pattern.

In one aspect, the first filter element is configured to pass one or more color components of visible light. The second filter element is configured to pass an infra-red light.

In one aspect, the first filter elements of the plurality of filter arrays are arranged based on a Bayer pattern.

In one aspect, the first filter element comprises a first filter and a second filter forming a stack along the second axis.

In one aspect, the apparatus further comprises a separation wall between adjacent filter elements overlaid on a pixel cell and between adjacent filter elements overlaid on adjacent pixel cells.

In one aspect, the separation wall is configured to reflect light that enters a filter element of the each filter array from the each microlens towards the photodiode on which the filter element is overlaid.

In one aspect, the separation wall includes a metallic material.

In one aspect, the apparatus further comprises an optical layer interposed between the plurality of filter arrays and the semiconductor substrate. The optical layer includes at least one of: an anti-reflection layer, or a pattern of micro-pyramids configured to direct infra-red light to at least one of the first photodiode or the second photodiode.

In one aspect, the apparatus further comprises an isolation structure interposed between adjacent photodiodes of the each pixel cell and adjacent photodiodes of adjacent pixel cells.

In one aspect, the isolation structure comprises a deep trench isolation (DTI), the DTI comprising insulator layers and a metallic filling layer sandwiched between the insulator layers.

In one aspect, the first photodiode and the second photodiode of the each pixel cell are pinned photodiodes.

In one aspect, a back side surface of the semiconductor substrate is configured as a light receiving surface from which the first photodiode and the second photodiode of the each pixel cell receive light. The semiconductor further comprises, in the each pixel cell, floating drains configured to store charge generated by the first photodiode and the second photodiode of the each pixel cell. The apparatus further comprises polysilicon gates formed on a front side surface of the semiconductor substrate opposite to the back side surface to control flow of the charge from the first photodiode and the second photodiode to the floating drains of the each pixel cell.

In one aspect, a front side surface of the semiconductor substrate is configured as a light receiving surface from which the first photodiode and the second photodiode of the each pixel cell receive light. The semiconductor further comprises, in the each pixel cell, floating drains configured to store charge generated by the first photodiode and the second photodiode of the each pixel cell. The apparatus further comprises polysilicon gates formed on the front side surface of the semiconductor substrate to control flow of the charge from the first photodiode and the second photodiode to the floating drains of the each pixel cell.

In one aspect, the semiconductor substrate is a first semiconductor substrate. The apparatus further comprises a second semiconductor substrate comprising a quantizer to quantize charge generated by the first photodiode and the second photodiode of the each pixel cell. The first semiconductor substrate and the second semiconductor substrate form a stack.

In one aspect, the second semiconductor substrate further includes an imaging module configured to: generate a first image based on the quantized charge of the first photodiode of the each pixel cell; and generate a second image based on the quantized charge of the second photodiode of the each pixel cell. Each pixel of the first image corresponds to each pixel of the second image.

In one aspect, each pixel of the first image and each pixel of the second image are generated based on charge generated by the first photodiode and the second photodiode within an exposure period.

### BRIEF DESCRIPTION OF THE DRAWINGS

Illustrative embodiments are described with reference to the following figures:

FIG. 1A and FIG. 1B are diagrams of an embodiment of a near-eye display.

FIG. 2 is an embodiment of a cross section of the near-eye display.

FIG. 3 illustrates an isometric view of an embodiment of a waveguide display.

FIG. 4 illustrates a cross section of an embodiment of the waveguide display.

FIG. 5 is a block diagram of an embodiment of a system including the near-eye display.

FIG. 6 illustrates an example of an image sensor including a multi-photodiode pixel cell.

FIG. 7A, FIG. 7B, and FIG. 7C illustrate examples of operations of the image sensor of FIG. 6.

FIG. 8A and FIG. 8B illustrate example components of the image sensor of FIG. 6.

FIG. 9A and FIG. 9B illustrate additional example components of the image sensor of FIG. 6.

FIG. 10A, FIG. 10B, FIG. 10C, and FIG. 10D illustrate additional example components of the image sensor of FIG. 6.

FIG. 11A, FIG. 11B, and FIG. 11C illustrate additional example components of the pixel cells of image sensor of FIG. 6.

FIG. 12 illustrates an example circuit schematic of the image sensor of FIG. 6.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

In the following description, for the purposes of explanation, specific details are set forth in order to provide a thorough understanding of certain inventive embodiments. However, it will be apparent that various embodiments may be practiced without these specific details. The figures and description are not intended to be restrictive.

A typical image sensor typically includes an array of pixel cells. Each pixel cell may have a photodiode to sense incident light by converting photons into charge (e.g., electrons or holes). For improved noise and dark current performances, a pinned photodiode can be included in the pixel to convert the photons into charge. The charge can be sensed by a charge sensing device, such as a floating drain region and/or other capacitors, which can convert the charge to a voltage. A pixel value can be generated based on the voltage. The pixel value can represent an intensity of light received by the pixel cell. An image comprising an array of pixels can be derived from the digital outputs of the voltages output by an array of pixel cells.

An image sensor can be used to perform different modes of imaging, such as 2D and 3D sensing. The 2D and 3D sensing can be performed based on light of different wavelength ranges. For example, visible light can be used for 2D sensing, whereas invisible light (e.g., infra-red light) can be used for 3D sensing. An image sensor may include an optical filter array to allow visible light of different optical wavelength ranges and colors (e.g., red, green, and blue colors) to a first set of pixel cells assigned for 2D sensing, and invisible light to a second set of pixel cells assigned for 3D sensing.

To perform 2D sensing, a photodiode at a pixel cell can generate charge at a rate that is proportional to an intensity of visible light incident upon the pixel cell, and the quantity of charge accumulated in an exposure period can be used to represent the intensity of visible light (or a certain color component of the visible light). The charge can be stored temporarily at the photodiode and then transferred to a capacitor (e.g., a floating diffusion) to develop a voltage.

The voltage can be sampled and quantized by an analog-to-digital converter (ADC) to generate an output corresponding to the intensity of visible light. An image pixel value can be generated based on the outputs from multiple pixel cells configured to sense different color components of the visible light (e.g., red, green, and blue colors).

Moreover, to perform 3D sensing, light of a different wavelength range (e.g., infra-red light) can be projected onto an object, and the reflected light can be detected by the pixel cells. The light can include structured light, light pulses, etc. The pixel cells outputs can be used to perform depth sensing operations based on, for example, detecting patterns of the reflected structured light, measuring a time-of-flight of the light pulse, etc. To detect patterns of the reflected structured light, a distribution of quantities of charge generated by the pixel cells during the exposure time can be determined, and pixel values can be generated based on the voltages corresponding to the quantities of charge. For time-of-flight measurement, the timing of generation of the charge at the photodiodes of the pixel cells can be determined to represent the times when the reflected light pulses are received at the pixel cells. Time differences between when the light pulses are projected to the object and when the reflected light pulses are received at the pixel cells can be used to provide the time-of-flight measurement.

A pixel cell array can be used to generate information of a scene. In some examples, a subset (e.g., a first set) of the pixel cells within the array can be used to perform 2D sensing of the scene, and another subset (e.g., a second set) of the pixel cells within the array can be used to perform 3D sensing of the scene. The fusion of 2D and 3D imaging data are useful for many applications that provide virtual-reality (VR), augmented-reality (AR) and/or mixed reality (MR) experiences. For example, a wearable VR/AR/MR system may perform a scene reconstruction of an environment in which the user of the system is located. Based on the reconstructed scene, the VR/AR/MR can generate display effects to provide an interactive experience. To reconstruct a scene, a subset of pixel cells within a pixel cell array can perform 3D sensing to, for example, identify a set of physical objects in the environment and determine the distances between the physical objects and the user. Another subset of pixel cells within the pixel cell array can perform 2D sensing to, for example, capture visual attributes including textures, colors, and reflectivity of these physical objects. The 2D and 3D image data of the scene can then be merged to create, for example, a 3D model of the scene including the visual attributes of the objects. As another example, a wearable VR/AR/MR system can also perform a head tracking operation based on a fusion of 2D and 3D image data. For example, based on the 2D image data, the VR/AR/MR system can extract certain image features to identify an object. Based on the 3D image data, the VR/AR/MR system can track a location of the identified object relative to the wearable device worn by the user. The VR/AR/MR system can track the head movement based on, for example, tracking the change in the location of the identified object relative to the wearable device as the user's head moves.

Using different sets of pixel for 2D and 3D imaging, however, can pose a number of challenges. First, because only a subset of the pixel cells of the array is used to perform either 2D imaging or 3D imaging, the spatial resolutions of both of the 2D image and 3D image are lower than the maximum spatial resolution available at the pixel cell array. Although the resolutions can be improved by including more pixel cells, such an approach can lead to increases in the form-factor of the image sensor as well as power consumption, both of which are undesirable especially for a wearable device.

Moreover, since pixel cells assigned to measure light of different wavelength ranges (for 2D and 3D imaging) are not collocated, different pixel cells may capture information of different spots of a scene, which can complicate the mapping between 2D and 3D images. For example, a pixel cell that receives a certain color component of visible light (for 2D imaging) and a pixel cell that receives invisible light (for 3D imaging) may also capture information of different spots of the scene. The output of these pixel cells cannot be simply merged to generate the 2D and 3D images. The lack of correspondence between the output of the pixel cells due to their different locations can be worsened when the pixel cell array is capturing 2D and 3D images of a moving object. While there are processing techniques available to correlate different pixel cell outputs to generate pixels for a 2D image, and to correlate between 2D and 3D images (e.g., interpolation), these techniques are typically computation-intensive and can also increase power consumption.

The present disclosure relates to an image sensor to provide collocated sensing of light of different wavelengths. The image sensor includes a plurality of pixel cells, each pixel cell including a first photodiode and a second photodiode arranged along a first axis (e.g., a horizontal axis). The image sensor further includes a plurality of filter arrays, each filter array including a first filter and a second filter overlaid on the each pixel cell along a second axis perpendicular to the first axis (e.g., along a vertical axis). The first filter of the each filter array is overlaid on the first photodiode of the each pixel cell, whereas the second filter of the filter array overlaid on the second photodiode of the each filter cell. The first filter and the second filter of the each filter array have different wavelength passbands, to enable the first photodiode and the second photodiode of the each pixel cell to sense light of different wavelengths. The image sensor further includes a plurality of microlenses. Each microlens is overlaid on the each filter array (and the each pixel cell) and configured to direct light from a spot of a scene via the first filter and the second filter of the each filter array to, respectively, the first photodiode and the second photodiode of the each pixel cell. Both the first photodiode and the second photodiode can be part of a semiconductor substrate.

The image sensor further includes a controller to enable the first photodiode of the each pixel cell to generate a first charge representing an intensity of a first light component of a first wavelength received from the spot and via the first filter, and to enable the second photodiode of the each pixel cell to generate a second charge representing an intensity of a second light component of a second wavelength received from the spot and via the second filter. The first wavelength and the second wavelength may be different among the plurality of pixel cells and are configured by the filter arrays. The image sensor further includes a quantizer to quantize the first charge and the second charge of the each pixel cell to, respectively, a first digital value and a second digital value for a pixel. A first image can be generated based on the first digital value of the pixels, whereas a second image can be generated based on the second digital value of the pixels, with each pixel of the first image and of the second image generated based on, respectively, the first digital output and the second digital output of the same pixel cell.

With the examples of the present disclosure, collocated sensing of light of different wavelengths can be performed as both the first photodiode and the second photodiode receive light from the same spot in a scene, which can simplify the mapping/correlation process between the first image and the second image. For example, in a case where the first photodiode senses a visible light component (e.g., one of red, green, blue, or monochrome) whereas the second photodiode senses infra-red light, the image sensor can support collocated 2D and 3D imaging, and the mapping/correlation processing between a 2D image frame (e.g., the first image frame) and a 3D image frame (e.g., the second image frame) can be simplified, as each pixel of both image frames represents light from the same spot of the scene. For similar reasons, in a case where the first and second photodiodes sense different light components of visible light, the mapping/correlation processing of image frames of different visible light components to form a 2D image frame can also be simplified. All these can substantially enhance the performance of the image sensor and the applications that rely on the image sensor outputs.

The image sensor according to the examples of the present disclosure may include additional features to improve the collocated sensing operations. Specifically, the image sensor can include features to enhance the absorption of light by the first photodiode and the second photodiode of the each pixel cell. For example, the image sensor may include a camera lens overlaid on the plurality of microlenses to collect and focus light from the scene. Each pixel cell can be positioned with respect to the each microlens and the camera lens such that the pixel cell and the exit pupil of the camera lens are at conjugate points of the each microlens. Such arrangements allow light from a spot of the scene, upon exiting through the exit pupil of the cameras lens and further refracted by the microlens, can be evenly distributed between the first photodiode and the second photodiode. The microlens can also be designed such that its focal point to be in front of the filter array, to enable the light to be spread out. Further, a structure, such as an anti-reflection layer (e.g., a layer having lower refractive index than the semiconductor substrate that includes the photodiodes), an infra-red absorption-enhancing structure (e.g., a micro-pyramid structured thin film), etc., can be interposed between the filter array and the photodiodes, to reduce reflection of the incident light away from the photodiodes and/or increase the intensity of the incident light that enters the photodiodes. All these can improve the absorption of light by the first photodiode and the second photodiode of the each pixel cell and improve the performance of the image sensor.

In addition, the image sensor may include features to reduce noise in the first charge and in the second charge generated by, respectively, the first photodiode and the second photodiode. The noise can refer to a component of the charge generated by the photodiode not due to the target light component to be detected by the photodiode. There are various sources of noise, including optical crosstalk between light of different wavelengths, charge leakage between photodiodes, dark charge, etc. The optical crosstalk may include a light component outside the target wavelength range to be sensed by the photodiode. In the example above, the first photodiode of a pixel cell may be configured, based on the first filter overlaid on the first photodiode, to detect the first light component of the first wavelength. For the first photodiode, the optical crosstalk may include light components of other wavelengths other than the first wavelength, which may include the second light component of the second wavelength to be detected by the second photodiode. Moreover, for the second photodiode, the optical crosstalk may include light components of other wavelengths other than the second wavelength, which may include the first light component of the first wavelength to be detected by the first photodiode. Moreover, charge leakage may occur due to movement of the first charge from the first photodiode to the second photodiode, or vice versa. Further, dark charge may occur due to dark current generated at the defects of a surface of the semiconductor substrate that includes the photodiodes.

In some examples, the image sensor can include features to mitigate the effect of optical crosstalk, charge leakage, and dark charge to reduce noise and to improve the performance of the image sensor. For example, the image sensor may include an optical insulator to separate between the first filter and the second filter in each filter array. The optical insulator can be configured as sidewalls that surround each side surfaces of the first filter and the second filter. The optical insulator can be configured as reflectors (e.g., metallic reflectors) to direct the light components passed by a filter to only the photodiode overlaid by the filter, but not to other photodiodes. For example, the optical insulator can direct the first light component only to the first photodiode but not to the second photodiode, and direct the second light component only to the second photodiode but not to the first photodiode. Moreover, the semiconductor substrate may include an electrical insulator, such as a deep trench isolation (DTI) structure between the first photodiode and the second photodiode, to prevent charge from moving between the first photodiode and the second photodiode. The DTI structure can also be filled with reflective materials, such as metals, so that the DTI structure can also function as an optical insulator to reduce optical crosstalk between the photodiodes within the semiconductor substrate. Further, the first photodiode and the second photodiode can be implemented as pinned photodiodes to become isolated from the surface defects of the semiconductor substrate, to mitigate the effect of dark current. All these arrangements can reduce noise present in the charge generated by each photodiode and improve the performance of the image sensor.

Examples of the present disclosure may include, or be implemented in conjunction with, an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

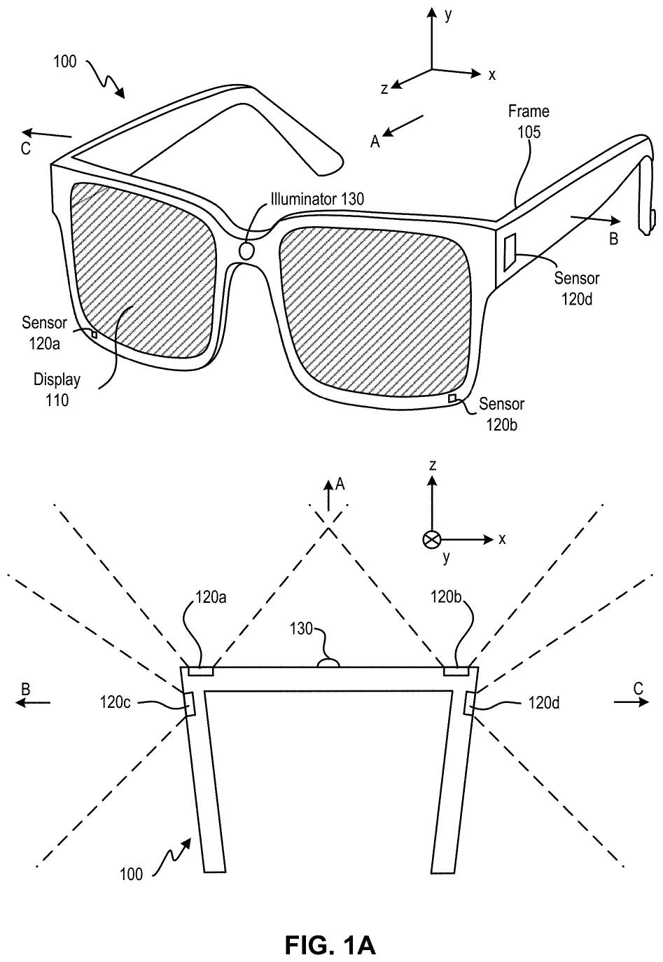

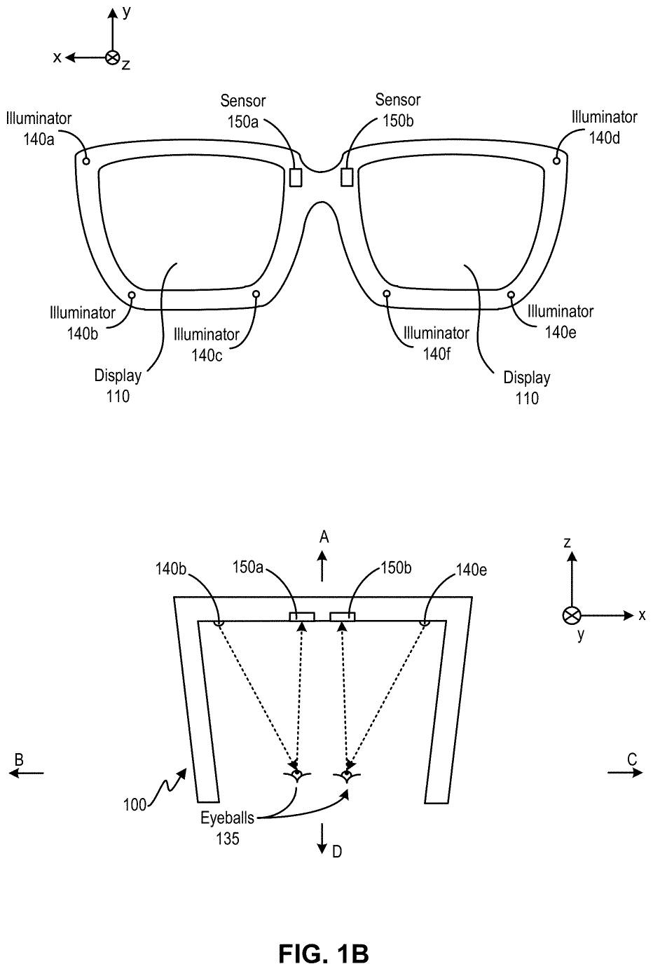

FIG. 1A is a diagram of an example of a near-eye display 100. Near-eye display 100 presents media to a user. Examples of media presented by near-eye display 100 include one or more images, video, and/or audio. In some embodiments, audio is presented via an external device (e.g., speakers and/or headphones) that receives audio information from the near-eye display 100, a console, or both, and presents audio data based on the audio information. Near-eye display 100 is generally configured to operate as a virtual reality (VR) display. In some embodiments, near-eye display 100 is modified to operate as an augmented reality (AR) display and/or a mixed reality (MR) display.

Near-eye display 100 includes a frame 105 and a display 110. Frame 105 is coupled to one or more optical elements. Display 110 is configured for the user to see content presented by near-eye display 100. In some embodiments, display 110 comprises a waveguide display assembly for directing light from one or more images to an eye of the user.

Near-eye display 100 further includes image sensors 120a, 120b, 120c, and 120d. Each of image sensors 120a, 120b, 120c, and 120d may include a pixel cell array comprising an array of pixel cells and configured to generate image data representing different fields of views along different directions. For example, sensors 120a and 120b may be configured to provide image data representing two field of views towards a direction A along the Z axis, whereas sensor 120c may be configured to provide image data representing a field of view towards a direction B along the X axis, and sensor 120d may be configured to provide image data representing a field of view towards a direction C along the X axis.

In some embodiments, sensors 120a-120d can be configured as input devices to control or influence the display content of the near-eye display 100, to provide an interactive VR/AR/MR experience to a user who wears near-eye display 100. For example, sensors 120a-120d can generate physical image data of a physical environment in which the user is located. The physical image data can be provided to a location tracking system to track a location and/or a path of movement of the user in the physical environment. A system can then update the image data provided to display 110 based on, for example, the location and orientation of the user, to provide the interactive experience. In some embodiments, the location tracking system may operate a SLAM algorithm to track a set of objects in the physical environment and within a view of field of the user as the user moves within the physical environment. The location tracking system can construct and update a map of the physical environment based on the set of objects, and track the location of the user within the map. By providing image data corresponding to multiple fields of views, sensors 120a-120d can provide the location tracking system a more holistic view of the physical environment, which can lead to more objects to be included in the construction and updating of the map. With such arrangement, the accuracy and robustness of tracking a location of the user within the physical environment can be improved.

In some embodiments, near-eye display 100 may further include one or more active illuminator 130 to project light into the physical environment. The light projected can be associated with different frequency spectrums (e.g., visible light, infra-red light, ultra-violet light, etc.), and can serve various purposes. For example, illuminator 130 may project light and/or light patterns in a dark environment (or in an environment with low intensity of infra-red light, ultra-violet light, etc.) to assist sensors 120a-120d in capturing 3D images of different objects within the dark environments. The 3D images may include, for example, pixel data representing the distances between the objects and near-eye display 100. The distance information can be used to, for example, construct a 3D model of the scene, to track a head movement of the user, to track a location of the user, etc. As to be discussed in more detail below, sensors 120a-120d can be operated in a first mode for 2D sensing and in a second mode for 3D sensing at different times. The 2D and 3D image data can be merged and provided to a system to provide a more robust tracking of, for example, the location of the user, the head movement of the user, etc.

FIG. 1B is a diagram of another embodiment of near-eye display 100. FIG. 1B illustrates a side of near-eye display 100 that faces the eyeball(s) 135 of the user who wears near-eye display 100. As shown in FIG. 1B, near-eye display 100 may further include a plurality of illuminators 140a, 140b, 140c, 140d, 140e, and 140f. Near-eye display 100 further includes a plurality of image sensors 150a and 150b. Illuminators 140a, 140b, and 140c may emit lights of certain optical frequency range (e.g., NIR) towards direction D (which is opposite to direction A of FIG. 1A). The emitted light may be associated with a certain pattern, and can be reflected by the left eyeball of the user. Sensor 150a may include a pixel cell array to receive the reflected light and generate an image of the reflected pattern. Similarly, illuminators 140d, 140e, and 140f may emit NIR lights carrying the pattern. The NIR lights can be reflected by the right eyeball of the user, and may be received by sensor 150b. Sensor 150b may also include a pixel cell array to generate an image of the reflected pattern. Based on the images of the reflected pattern from sensors 150a and 150b, the system can determine a gaze point of the user, and update the image data provided to near-eye display 100 based on the determined gaze point to provide an interactive experience to the user. In some examples, image sensors 150a and 150b may include same pixel cells as sensors 120a-120d.

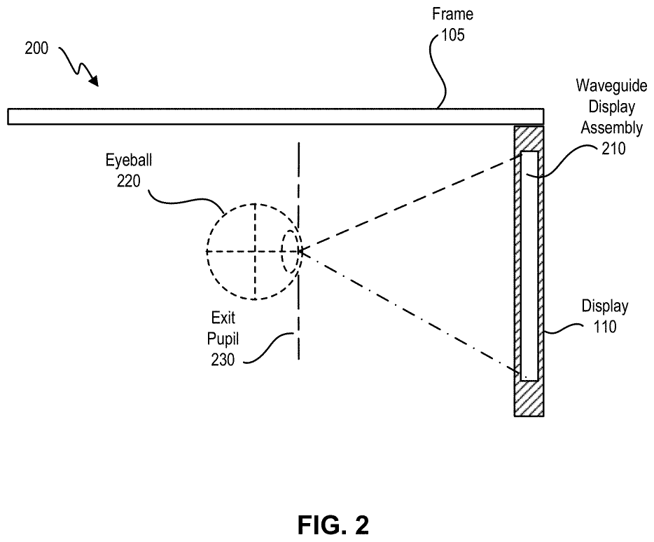

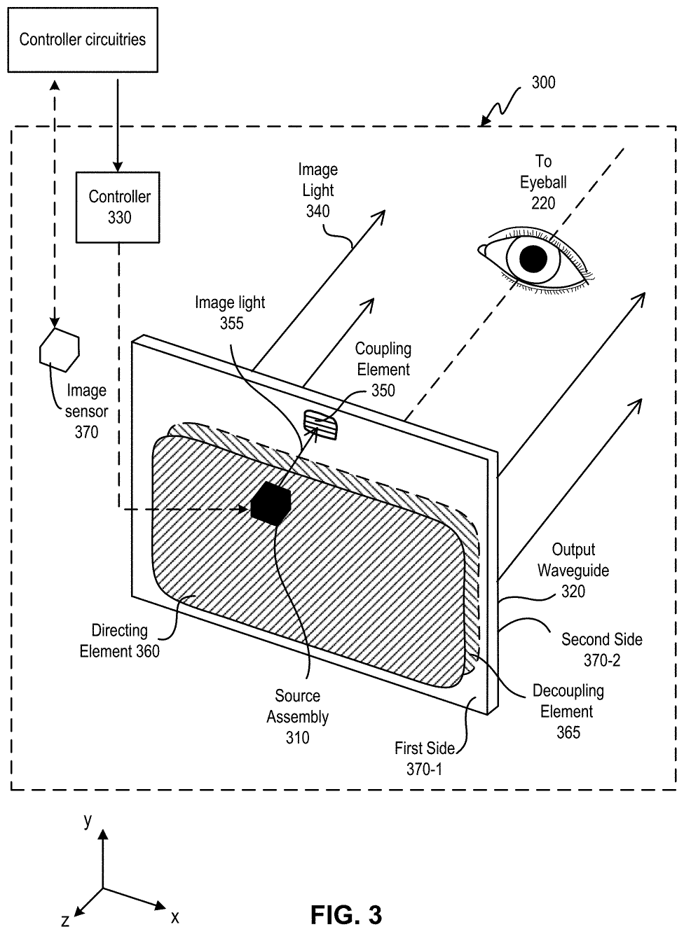

FIG. 2 is an embodiment of a cross section 200 of near-eye display 100 illustrated in FIG. 1. Display 110 includes at least one waveguide display assembly 210. An exit pupil 230 is a location where a single eyeball 220 of the user is positioned in an eyebox region when the user wears the near-eye display 100. For purposes of illustration, FIG. 2 shows the cross section 200 associated eyeball 220 and a single waveguide display assembly 210, but a second waveguide display is used for a second eye of a user.

Waveguide display assembly 210 is configured to direct image light to an eyebox located at exit pupil 230 and to eyeball 220. Waveguide display assembly 210 may be composed of one or more materials (e.g., plastic, glass, etc.) with one or more refractive indices. In some embodiments, near-eye display 100 includes one or more optical elements between waveguide display assembly 210 and eyeball 220.

In some embodiments, waveguide display assembly 210 includes a stack of one or more waveguide displays including, but not restricted to, a stacked waveguide display, a varifocal waveguide display, etc. The stacked waveguide display is a polychromatic display (e.g., a red-green-blue (RGB) display) created by stacking waveguide displays whose respective monochromatic sources are of different colors. The stacked waveguide display is also a polychromatic display that can be projected on multiple planes (e.g., multi-planar colored display). In some configurations, the stacked waveguide display is a monochromatic display that can be projected on multiple planes (e.g., multi-planar monochromatic display). The varifocal waveguide display is a display that can adjust a focal position of image light emitted from the waveguide display. In alternate embodiments, waveguide display assembly 210 may include the stacked waveguide display and the varifocal waveguide display.

FIG. 3 illustrates an isometric view of an embodiment of a waveguide display 300. In some embodiments, waveguide display 300 is a component (e.g., waveguide display assembly 210) of near-eye display 100. In some embodiments, waveguide display 300 is part of some other near-eye display or other system that directs image light to a particular location.

Waveguide display 300 includes a source assembly 310, an output waveguide 320, an illuminator 325, and a controller 330. Illuminator 325 can include illuminator 130 of FIG. 1A. For purposes of illustration, FIG. 3 shows the waveguide display 300 associated with a single eyeball 220, but in some embodiments, another waveguide display separate, or partially separate, from the waveguide display 300 provides image light to another eye of the user.

Source assembly 310 generates image light 355. Source assembly 310 generates and outputs image light 355 to a coupling element 350 located on a first side 370-1 of output waveguide 320. Output waveguide 320 is an optical waveguide that outputs expanded image light 340 to an eyeball 220 of a user. Output waveguide 320 receives image light 355 at one or more coupling elements 350 located on the first side 370-1 and guides received input image light 355 to a directing element 360. In some embodiments, coupling element 350 couples the image light 355 from source assembly 310 into output waveguide 320. Coupling element 350 may be, e.g., a diffraction grating, a holographic grating, one or more cascaded reflectors, one or more prismatic surface elements, and/or an array of holographic reflectors.

Directing element 360 redirects the received input image light 355 to decoupling element 365 such that the received input image light 355 is decoupled out of output waveguide 320 via decoupling element 365. Directing element 360 is part of, or affixed to, first side 370-1 of output waveguide 320. Decoupling element 365 is part of, or affixed to, second side 370-2 of output waveguide 320, such that directing element 360 is opposed to the decoupling element 365. Directing element 360 and/or decoupling element 365 may be, e.g., a diffraction grating, a holographic grating, one or more cascaded reflectors, one or more prismatic surface elements, and/or an array of holographic reflectors.

Second side 370-2 represents a plane along an x-dimension and a y-dimension. Output waveguide 320 may be composed of one or more materials that facilitate total internal reflection of image light 355. Output waveguide 320 may be composed of e.g., silicon, plastic, glass, and/or polymers. Output waveguide 320 has a relatively small form factor. For example, output waveguide 320 may be approximately 50 mm wide along x-dimension, 30 mm long along y-dimension and 0.5-1 mm thick along a z-dimension.

Controller 330 controls scanning operations of source assembly 310. The controller 330 determines scanning instructions for the source assembly 310. In some embodiments, the output waveguide 320 outputs expanded image light 340 to the user's eyeball 220 with a large field of view (FOV). For example, the expanded image light 340 is provided to the user's eyeball 220 with a diagonal FOV (in x and y) of 60 degrees and/or greater and/or 150 degrees and/or less. The output waveguide 320 is configured to provide an eyebox with a length of 20 mm or greater and/or equal to or less than 50 mm; and/or a width of 10 mm or greater and/or equal to or less than 50 mm.

Moreover, controller 330 also controls image light 355 generated by source assembly 310, based on image data provided by image sensor 370. Image sensor 370 may be located on first side 370-1 and may include, for example, image sensors 120a-120d of FIG. 1A. Image sensors 120a-120d can be operated to perform 2D sensing and 3D sensing of, for example, an object 372 in front of the user (e.g., facing first side 370-1). For 2D sensing, each pixel cell of image sensors 120a-120d can be operated to generate pixel data representing an intensity of light 374 generated by a light source 376 and reflected off object 372. For 3D sensing, each pixel cell of image sensors 120a-120d can be operated to generate pixel data representing a time-of-flight measurement for light 378 generated by illuminator 325. For example, each pixel cell of image sensors 120a-120d can determine a first time when illuminator 325 is enabled to project light 378 and a second time when the pixel cell detects light 378 reflected off object 372. The difference between the first time and the second time can indicate the time-of-flight of light 378 between image sensors 120a-120d and object 372, and the time-of-flight information can be used to determine a distance between image sensors 120a-120d and object 372. Image sensors 120a-120d can be operated to perform 2D and 3D sensing at different times, and provide the 2D and 3D image data to a remote console 390 that may be (or may be not) located within waveguide display 300. The remote console may combine the 2D and 3D images to, for example, generate a 3D model of the environment in which the user is located, to track a location and/or orientation of the user, etc. The remote console may determine the content of the images to be displayed to the user based on the information derived from the 2D and 3D images. The remote console can transmit instructions to controller 330 related to the determined content. Based on the instructions, controller 330 can control the generation and outputting of image light 355 by source assembly 310, to provide an interactive experience to the user.

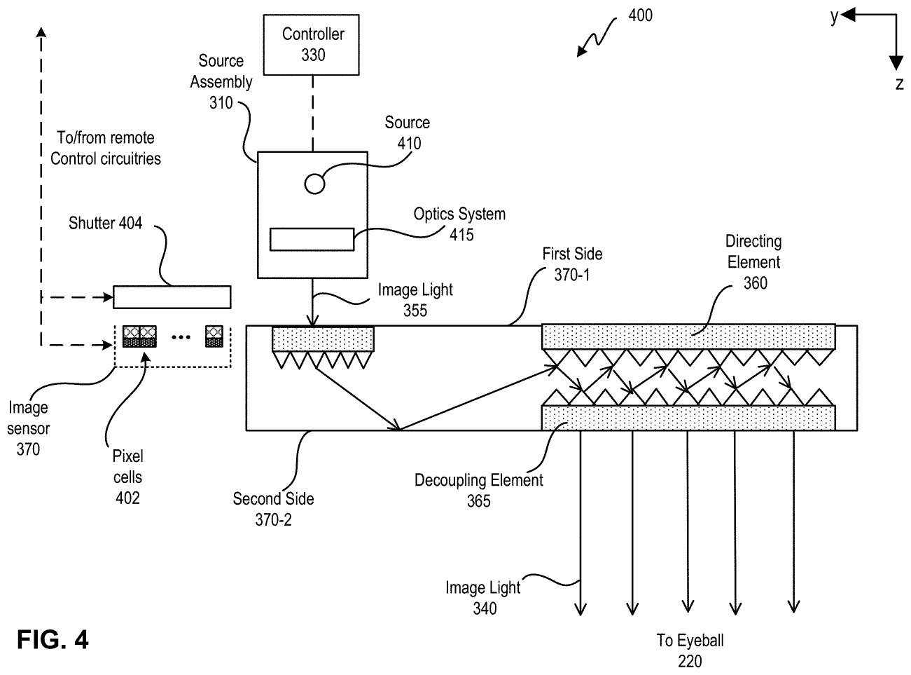

FIG. 4 illustrates an embodiment of a cross section 400 of the waveguide display 300. The cross section 400 includes source assembly 310, output waveguide 320, and image sensor 370. In the example of FIG. 4, image sensor 370 may include a set of pixel cells 402 located on first side 370-1 to generate an image of the physical environment in front of the user. In some embodiments, there can be a mechanical shutter 404 and an optical filter array 406 interposed between the set of pixel cells 402 and the physical environment. Mechanical shutter 404 can control the exposure of the set of pixel cells 402. In some embodiments, the mechanical shutter 404 can be replaced by an electronic shutter gate, as to be discussed below. Optical filter array 406 can control an optical wavelength range of light the set of pixel cells 402 is exposed to, as to be discussed below. Each of pixel cells 402 may correspond to one pixel of the image. Although not shown in FIG. 4, it is understood that each of pixel cells 402 may also be overlaid with a filter to control the optical wavelength range of the light to be sensed by the pixel cells.

After receiving instructions from the remote console, mechanical shutter 404 can open and expose the set of pixel cells 402 in an exposure period. During the exposure period, image sensor 370 can obtain samples of lights incident on the set of pixel cells 402, and generate image data based on an intensity distribution of the incident light samples detected by the set of pixel cells 402. Image sensor 370 can then provide the image data to the remote console, which determines the display content, and provide the display content information to controller 330. Controller 330 can then determine image light 355 based on the display content information.

Source assembly 310 generates image light 355 in accordance with instructions from the controller 330. Source assembly 310 includes a source 410 and an optics system 415. Source 410 is a light source that generates coherent or partially coherent light. Source 410 may be, e.g., a laser diode, a vertical cavity surface emitting laser, and/or a light emitting diode.

Optics system 415 includes one or more optical components that condition the light from source 410. Conditioning light from source 410 may include, e.g., expanding, collimating, and/or adjusting orientation in accordance with instructions from controller 330. The one or more optical components may include one or more lenses, liquid lenses, mirrors, apertures, and/or gratings. In some embodiments, optics system 415 includes a liquid lens with a plurality of electrodes that allows scanning of a beam of light with a threshold value of scanning angle to shift the beam of light to a region outside the liquid lens. Light emitted from the optics system 415 (and also source assembly 310) is referred to as image light 355.

Output waveguide 320 receives image light 355. Coupling element 350 couples image light 355 from source assembly 310 into output waveguide 320. In embodiments where coupling element 350 is diffraction grating, a pitch of the diffraction grating is chosen such that total internal reflection occurs in output waveguide 320, and image light 355 propagates internally in output waveguide 320 (e.g., by total internal reflection), toward decoupling element 365.

Directing element 360 redirects image light 355 toward decoupling element 365 for decoupling from output waveguide 320. In embodiments where directing element 360 is a diffraction grating, the pitch of the diffraction grating is chosen to cause incident image light 355 to exit output waveguide 320 at angle(s) of inclination relative to a surface of decoupling element 365.

In some embodiments, directing element 360 and/or decoupling element 365 are structurally similar. Expanded image light 340 exiting output waveguide 320 is expanded along one or more dimensions (e.g., may be elongated along x-dimension). In some embodiments, waveguide display 300 includes a plurality of source assemblies 310 and a plurality of output waveguides 320. Each of source assemblies 310 emits a monochromatic image light of a specific band of wavelength corresponding to a primary color (e.g., red, green, or blue). Each of output waveguides 320 may be stacked together with a distance of separation to output an expanded image light 340 that is multi-colored.

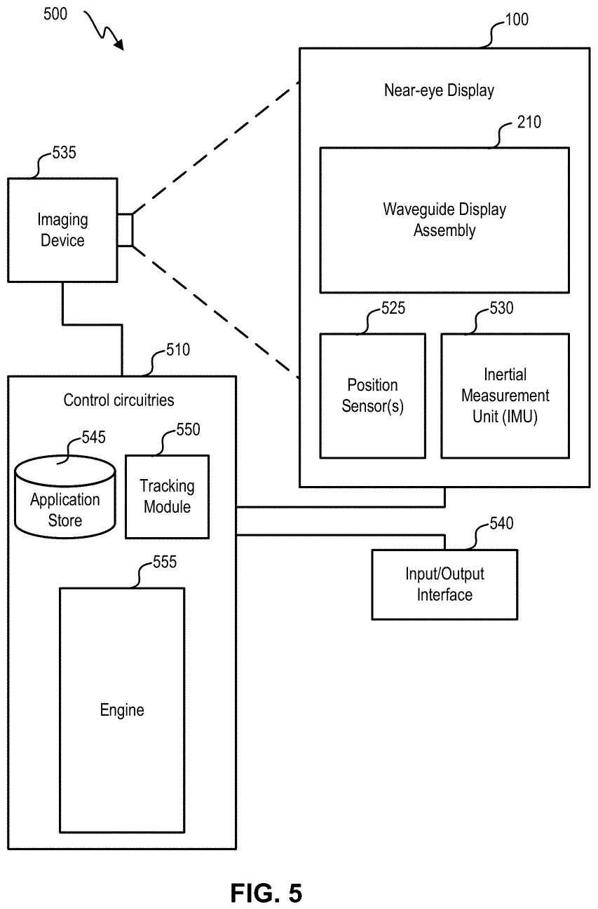

FIG. 5 is a block diagram of an embodiment of a system 500 including the near-eye display 100. The system 500 comprises near-eye display 100, an imaging device 535, an input/output interface 540, and image sensors 120a-120d and 150a-150b that are each coupled to control circuitries 510. System 500 can be configured as a head-mounted device, a wearable device, etc.

Near-eye display 100 is a display that presents media to a user. Examples of media presented by the near-eye display 100 include one or more images, video, and/or audio. In some embodiments, audio is presented via an external device (e.g., speakers and/or headphones) that receives audio information from near-eye display 100 and/or control circuitries 510 and presents audio data based on the audio information to a user. In some embodiments, near-eye display 100 may also act as an AR eyewear glass. In some embodiments, near-eye display 100 augments views of a physical, real-world environment, with computer-generated elements (e.g., images, video, sound, etc.).

Near-eye display 100 includes waveguide display assembly 210, one or more position sensors 525, and/or an inertial measurement unit (IMU) 530. Waveguide display assembly 210 includes source assembly 310, output waveguide 320, and controller 330.

IMU 530 is an electronic device that generates fast calibration data indicating an estimated position of near-eye display 100 relative to an initial position of near-eye display 100 based on measurement signals received from one or more of position sensors 525.

Imaging device 535 may generate image data for various applications. For example, imaging device 535 may generate image data to provide slow calibration data in accordance with calibration parameters received from control circuitries 510. Imaging device 535 may include, for example, image sensors 120a-120d of FIG. 1A for generating 2D image data and 3D image data of a physical environment in which the user is located to track the location and head movement of the user. Imaging device 535 may further include, for example, image sensors 150a-150b of FIG. 1B for generating image data (e.g., 2D image data) for determining a gaze point of the user, to identify an object of interest of the user.

The input/output interface 540 is a device that allows a user to send action requests to the control circuitries 510. An action request is a request to perform a particular action. For example, an action request may be to start or end an application or to perform a particular action within the application.

Control circuitries 510 provides media to near-eye display 100 for presentation to the user in accordance with information received from one or more of: imaging device 535, near-eye display 100, and input/output interface 540. In some examples, control circuitries 510 can be housed within system 500 configured as a head-mounted device. In some examples, control circuitries 510 can be a standalone console device communicatively coupled with other components of system 500. In the example shown in FIG. 5, control circuitries 510 include an application store 545, a tracking module 550, and an engine 555.

The application store 545 stores one or more applications for execution by the control circuitries 510. An application is a group of instructions, that, when executed by a processor, generates content for presentation to the user. Examples of applications include: gaming applications, conferencing applications, video playback application, or other suitable applications.

Tracking module 550 calibrates system 500 using one or more calibration parameters and may adjust one or more calibration parameters to reduce error in determination of the position of the near-eye display 100.

Tracking module 550 tracks movements of near-eye display 100 using slow calibration information from the imaging device 535. Tracking module 550 also determines positions of a reference point of near-eye display 100 using position information from the fast calibration information.

Engine 555 executes applications within system 500 and receives position information, acceleration information, velocity information, and/or predicted future positions of near-eye display 100 from tracking module 550. In some embodiments, information received by engine 555 may be used for producing a signal (e.g., display instructions) to waveguide display assembly 210 that determines a type of content presented to the user. For example, to provide an interactive experience, engine 555 may determine the content to be presented to the user based on a location of the user (e.g., provided by tracking module 550), a gaze point of the user (e.g., based on image data provided by imaging device 535), a distance between an object and user (e.g., based on image data provided by imaging device 535).

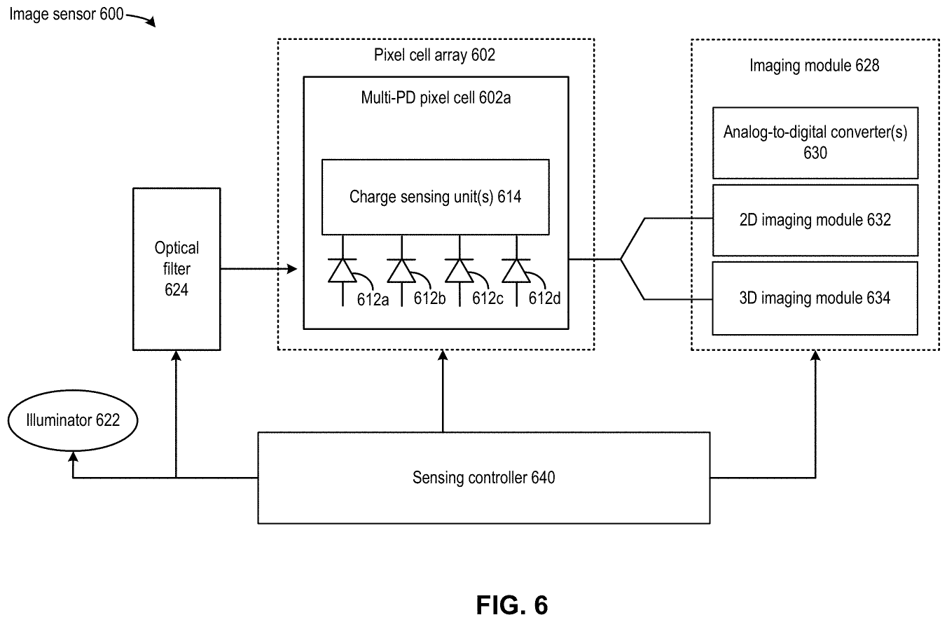

FIG. 6 illustrates an example of an image sensor 600. Image sensor 600 can be part of near-eye display 100, and can provide 2D and 3D image data to control circuitries 510 of FIG. 5 to control the display content of near-eye display 100. As shown in FIG. 6, image sensor 600 may include an array of pixel cells 602 including Multi-photodiode (multi-PD) pixel cell 602a (hereinafter, pixel cell 602a). Pixel cell 602a can include a plurality of photodiodes 612 including, for example, photodiodes 612a, 612b, 612c, and 612d, and one or more charge sensing units 614. The plurality of photodiodes 612 can convert different components of incident light to charge. For example, photodiode 612a-612c can correspond to different visible light channels, in which photodiode 612a can convert a visible blue component (e.g., a wavelength range of 450-490 nanometers (nm)) to charge. Photodiode 612b can convert a visible green component (e.g., a wavelength range of 520-560 nm) to charge. Photodiode 612c can convert a visible red component (e.g., a wavelength range of 635-700 nm) to charge. Moreover, photodiode 612d can convert an infra-red component (e.g., 700-1000 nm) to charge. Each of the one or more charge sensing units 614 can include a charge storage device and a buffer to convert the charge generated by photodiodes 612a-612d to voltages, which can be quantized into digital values. The digital values generated from photodiodes 612a-612c can represent the different visible light components of a pixel, and each can be used for 2D sensing in a particular visible light channel. Moreover, the digital value generated from photodiode 612d can represent the infra-red light component of the same pixel and can be used for 3D sensing. Although FIG. 6 shows that pixel cell 602a includes four photodiodes, it is understood that the pixel cell can include a different number of photodiodes (e.g., two, three, etc.).

In addition, image sensor 600 also includes an illuminator 622, an optical filter 624, an imaging module 628, and a sensing controller 630. Illuminator 622 may be an infra-red illuminator, such as a laser, a light emitting diode (LED), etc., that can project infra-red light for 3D sensing. The projected light may include, for example, structured light, light pulses, etc. Optical filter 624 may include an array of filter elements overlaid on the plurality of photodiodes 612a-612d of each pixel cell including pixel cell 602a. Each filter element can set a wavelength range of incident light received by each photodiode of pixel cell 602a. For example, a filter element over photodiode 612a may transmit the visible blue light component while blocking other components, a filter element over photodiode 612b may transmit the visible green light component, a filter element over photodiode 612c may transmit the visible red light component, whereas a filter element over photodiode 612d may transmit the infra-red light component.

Image sensor 600 further includes an imaging module 628, which can include one or more analog-to-digital converters (ADC) 630 to quantize the voltages from charge sensing units 614 into digital values. ADC 630 can be part of pixel cells array 602 or can be external to pixel cells 602. Imaging module 628 may further include a 2D imaging module 632 to perform 2D imaging operations and a 3D imaging module 634 to perform 3D imaging operations. The operations can be based on digital values provided by ADCs 630. For example, based on the digital values from each of photodiodes 612a-612c, 2D imaging module 632 can generate an array of pixel values representing an intensity of an incident light component for each visible color channel, and generate an image frame for each visible color channel. Moreover, 3D imaging module 634 can generate a 3D image based on the digital values from photodiode 612d. In some examples, based on the digital values, 3D imaging module 634 can detect a pattern of structured light reflected by a surface of an object, and compare the detected pattern with the pattern of structured light projected by illuminator 622 to determine the depths of different points of the surface with respect to the pixel cells array. For detection of the pattern of reflected light, 3D imaging module 634 can generate pixel values based on intensities of infra-red light received at the pixel cells. As another example, 3D imaging module 634 can generate pixel values based on time-of-flight of the infra-red light transmitted by illuminator 622 and reflected by the object.

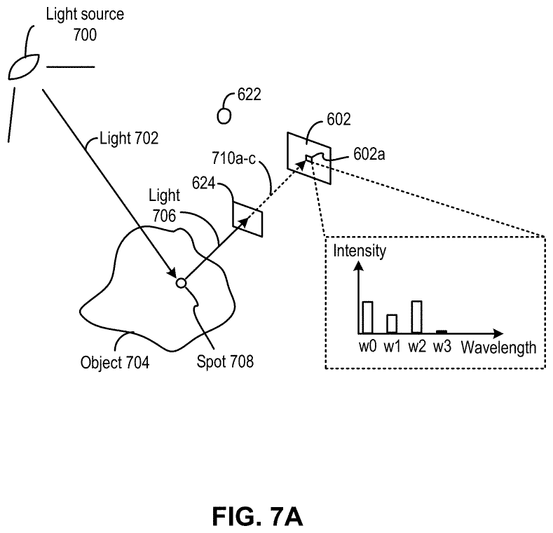

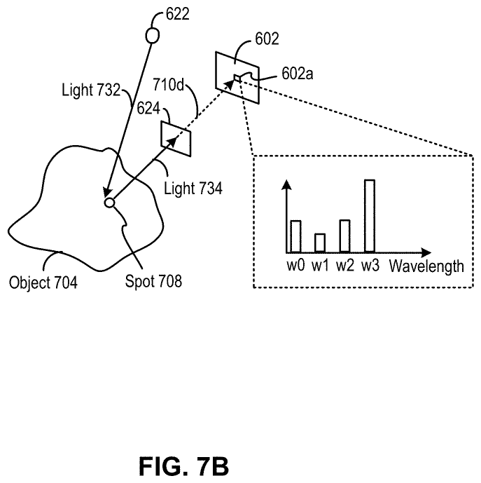

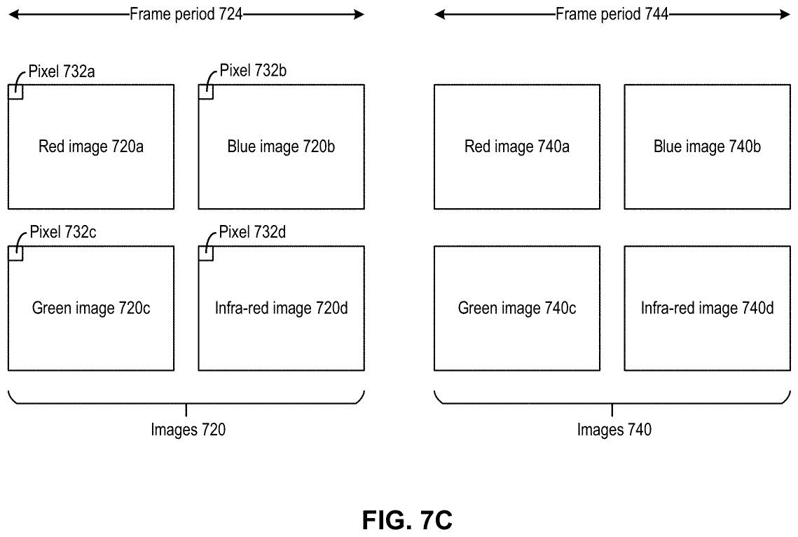

Image sensor 600 further includes a sensing controller 640 to control different components of image sensor 600 to perform 2D and 3D imaging of an object. Reference is now made to FIG. 7A-FIG. 7C, which illustrate examples of operations of image sensor 600 for 2D and 3D imaging. FIG. 7A illustrates an example of operations for 2D imaging. For 2D imaging, pixel cells array 606 can detect visible light in the environment including visible light reflected off an object. For example, referring to FIG. 7A, visible light source 700 (e.g., a light bulb, the sun, or other sources of ambient visible light) can project visible light 702 onto an object 704. Visible light 706 can be reflected off a spot 708 of object 704. Visible light 706 can be filtered by optical filter 624 to pass a pre-determined wavelength range w0 of the reflected visible light 706 to produce filtered light 710a for photodiode 612a. Optical filter 624 can pass a pre-determined wavelength range w1 of the reflected visible light 706 to produce filter light 710b for photodiode 612b, and a pre-determined wavelength range w2 of the reflected visible light 706 to produce filtered light 710c for photodiode 612c. The different wavelength ranges w0, w1, and w2 may correspond to different color components of visible light 706 reflected off spot 708. Filtered light 710a-c can be captured by, respectively, photodiodes 612a, 612b, and 612c of pixel cell 606a to generate and accumulate, respectively, first charge, second charge, and third charge within an exposure period. At the end of the exposure period, sensing controller 640 can steer the first charge, the second charge, and the third charge to charge sensing unit 614 to generate voltages representing the intensities of the different color components, and provide the voltages to imaging module 628. Imaging module 628 may include ADC 630 and can be controlled by sensing controller 640 to sample and quantize the voltages to generate digital values representing the intensities of the color components of visible light 706.

Referring to FIG. 7C, after the digital values are generated, sensing controller 640 can control 2D imaging module 632 to generate, based on the digital values, sets of images including a set of images 720, which includes a red image frame 720a, a blue image frame 720b, and a green image frame 720c each representing one of red, blue, or green color image of a scene within a frame period 724. Each pixel from the red image (e.g., pixel 732a), from the blue image (e.g., pixel 732b), and from the green image (e.g., pixel 732c) can represent visible components of light from the same spot (e.g., spot 708) of a scene. A different set of images 740 can be generated by 2D imaging module 632 in a subsequent frame period 744. Each of red image (e.g., red images 720a, 740a, etc.), blue image (e.g., blue images 720b, 740b, etc.), and green images (e.g., green images 720c, 740c, etc.) can represent the image of a scene captured in a specific color channel and at a particular time, and can be provided to an application to, for example, extract image features from the specific color channel. As each image captured within a frame period can represent the same scene, while each corresponding pixel of the images is generated based on detecting light from the same spot of the scene, the correspondence of images between different color channels can be improved.

Furthermore, image sensor 600 can also perform 3D imaging of object 704. Referring to FIG. 7B, sensing controller 640 can control illuminator 622 to project infra-red light 728, which can include a light pulse, structured light, etc., onto object 704. Infra-red light 728 can have a wavelength range of 700 nanometers (nm) to 1 millimeter (mm). Infra-red photons 730 can reflect off object 704 as reflected light 734 and propagate towards pixel cells array 606 and pass through optical filter 624, which can pass a pre-determined wavelength range w3 corresponding to the wavelength range of infra-red light as filtered light 710d for photodiode 612d. Photodiode 612d can convert filtered light 710d into a fourth charge. Sensing controller 640 can steer the fourth charge to charge sensing unit 614 to generate the a fourth voltage representing the intensity of the infra-red light received at the pixel cell. The detection and conversion of filtered light 710d by photodiode 612d can occur within the same exposure period as the detection and conversion of visible light 706 by photodiodes 612a-c, or in different exposure periods.

Referring back to FIG. 7C, after the digital values are generated, sensing controller 640 can control 3D imaging module 634 to generate, based on the digital values, an infra-red image 720d of the scene as part of images 720 captured within frame period 724 (or a different frame period). Moreover, 3D imaging module 634 can also generate an infra-red image 740d of the scene as part of images 740 captured within frame period 744 (or a different frame period). As each infra-red image can represent the same scene as other images captured within the same frame period albeit in a different channel (e.g., infra-red image 720d versus red, blue, and green images 720a-720c, infra-red image 740d versus red, blue, and green images 740a-740c, etc.), while each pixel of an infra-red image is generated based on detecting infra-red light from the same spot of the scene as other corresponding pixels in other images within the same frame period, the correspondence between 2D and 3D imaging can be improved as well.

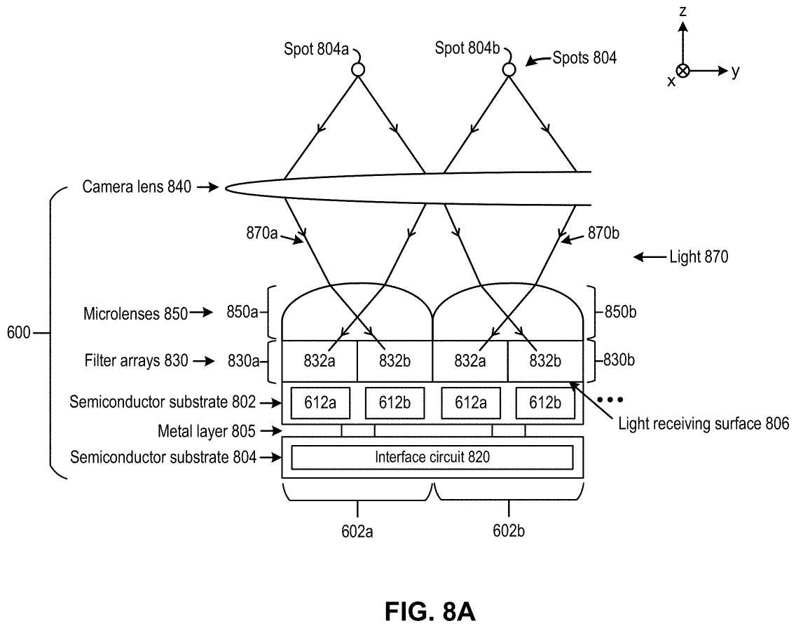

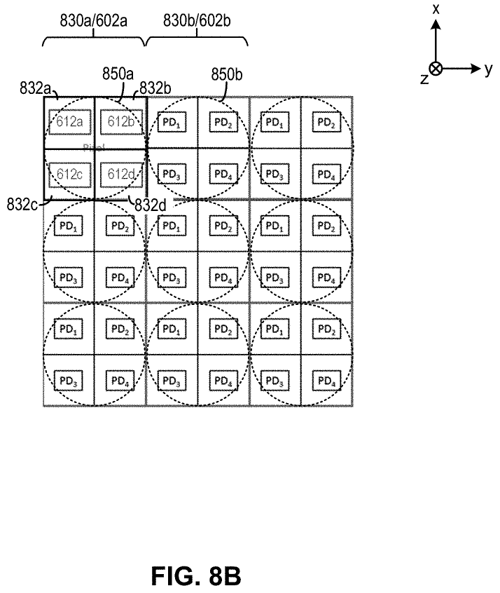

FIG. 8A and FIG. 8B illustrates additional components of image sensor 600. FIG. 8A illustrates a side view of image sensor 600 whereas FIG. 8B illustrates a top view of image sensor 600. As shown in FIG. 8A, image sensor 600 may include a semiconductor substrate 802, a semiconductor substrate 804, as well as a metal layer 805 sandwiched between the substrates. Semiconductor substrate 802 can include a light receiving surface 806 and the photodiodes (e.g., photodiodes 612a, 612b, 612c, and 612d) of pixel cells 602, including pixel cells 602a and 602b. The photodiodes are aligned along a first axis parallel with light receiving surface 806 (e.g., horizontal x-axis). Although FIG. 8B illustrates that the photodiodes have a rectangular shapes, it is understood that the photodiodes can have other shapes, such as square, diamond, etc. In the example of FIG. 8A and FIG. 8B, the photodiodes can be arranged in a 2×2 configuration in which each pixel cell 602 includes two photodiodes (e.g., photodiodes 612a and 612b) arranged on a side. Semiconductor substrate 802 may also include, in each pixel cell 602, charge sensing unit 614 to store the charge generated by the photodiodes.

In addition, semiconductor substrate 804 includes an interface circuit 820 which may include, for example, imaging module 628, ADC 630, sensing controller 640, etc., which can be shared by multiple pixel cells 602. In some examples, interface circuit 820 may include multiple charge sensing units 614 and/or multiple ADCs 630, with each pixel cell having dedicated access to a charge sensing unit 614 and/or a ADC 630. Metal layer 805 may include for example, metal interconnects to transfer the charge generated by the photodiodes to charge sensing unit 614 of interface circuit 820, as well as metal capacitors which can be part of the charge storage device of charge sensing unit 614 to convert the charge to voltages.

Moreover, image sensor 600 includes a plurality of filter arrays 830. The plurality of filter arrays 830 can be part of optical filter 624. Each filter array 830 is overlaid on a pixel cell 602 along a second axis perpendicular to the first axis (e.g., the vertical z-axis). For example, filter array 830a is overlaid on pixel cell 602a, filter array 830b is overlaid on pixel cell 602b, etc. Each filter array 830 controls the wavelength ranges of light to be sensed by the photodiodes of each pixel cell 602. For example, as shown in FIG. 8B, each filter array 830 includes a plurality of filter elements 832 including 832a, 832b, 832c and 832d. The filter elements of a filter array 830 are arranged in the same configuration as the photodiodes of a pixel cell 602 (e.g., in a 2×2 configuration), with each filter element 832 to control a wavelength range of a light component to be sensed by a photodiode. For example, filter element 832a is overlaid on photodiode 612a, whereas filter element 832b is overlaid on photodiode 612b. Moreover, filter element 832c is overlaid on photodiode 612c, whereas filter element 832d is overlaid on photodiode 612d. As to be described below, some or all of filter elements 832 within a filter array 830 may have different wavelength passing ranges. Moreover, different filter arrays 830 may have different combinations of filter elements to set different passing wavelength ranges for different pixel cells 602.

Further, image sensor 600 includes a camera lens 840 and a plurality of microlenses 850. Camera lens 840 is overlaid on plurality of microlenses 850 along the second axis to form a lens stack. Camera lens 840 can receive incident light 870 from a plurality of spots 860 of a scene and refract the incident light towards each microlens 850. Each microlens 850 is overlaid on a filter array 830 (and pixel cell 602) along the second axis and can refract incident light of a spot towards each photodiode of the pixel cell 602 under the filter array 830. For example, as shown in FIG. 8A, microlens 850a can receive incident light 870a from a spot 860a via camera lens 840 and project incident light 870a towards each photodiode 612 of pixel cell 602a. Moreover, microlens 850b can receive incident light 870b from a spot 860b via camera lens 840 and project incident light 870b towards each photodiode 612 of pixel cell 602b. With such arrangements, each photodiode 612 of a pixel cell 602 can receive a component of light from the same spot, with the wavelength and magnitude of the component controlled by the filter element 832 that overlays on the photodiode, to support collocated sensing of different components of light from that spot.

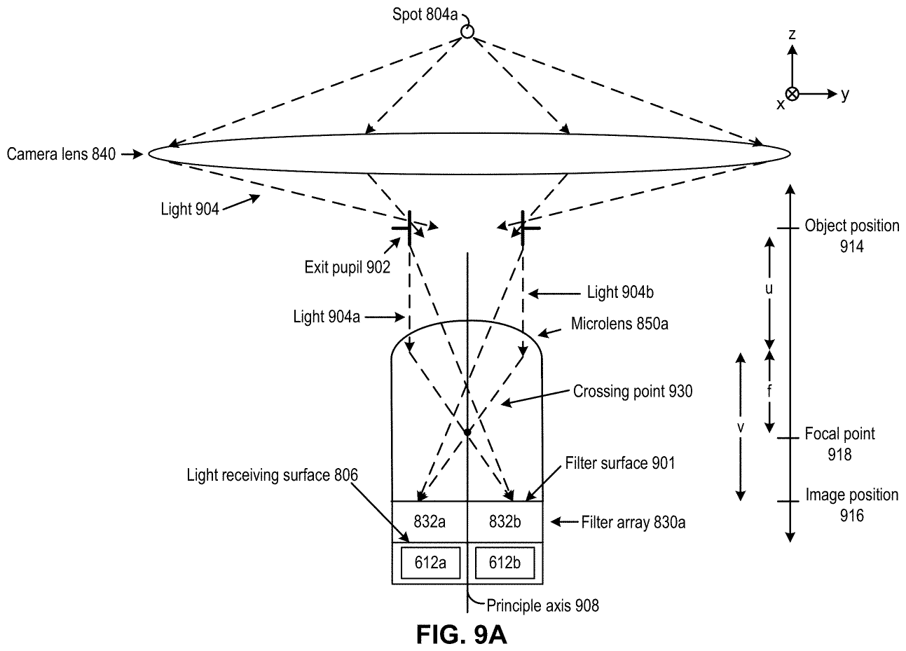

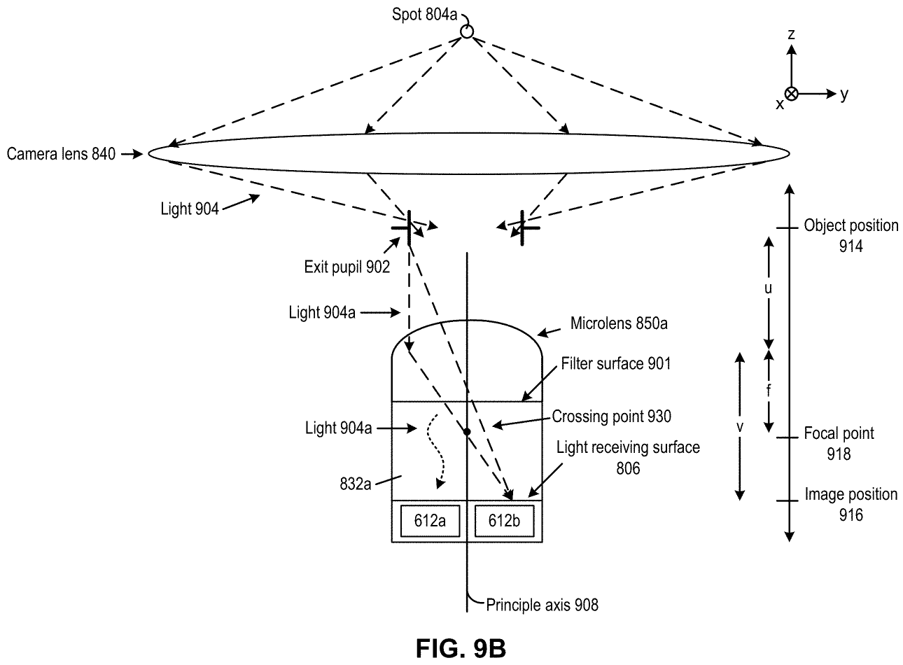

FIG. 9A and FIG. 9B illustrates different examples of arrangements of microlens 850a to direct light of the same spot to each photodiode 612 of a pixel cell 602a. In one example, as shown in FIG. 9A, a filter surface 901 of filter array 830, which faces camera lens 840, and exit pupil 902 of camera lens 840 can be positioned at conjugate positions of microlens 850a. Exit pupil 902 can define a virtual aperture of camera lens 840 such that only light that goes through exit pupil 902, such as light 904 from spot 804a, can exit camera lens 840. The location of exit pupil 902 with respect to camera lens 840 can be based on various physical and optical properties of camera lens 840 such as the curvature, the refractive index of the material of camera lens 840, the focal length, etc. The conjugate points of microlens 850a can define a pair of corresponding object position 914 and image position 916 of microlens 850a and can be defined based on the focal length f of microlens 850a with focal point 918. For example, with exit pupil 902 at object position 914 and at distance u from microlens 850, filter surface 901 can be at image position 916 of microlens 850a. The values of u, v, and f can be related based on the following lens equation:

$$\frac{1}{f} = \frac{1}{u} + \frac{1}{v} \qquad ( Equation 1 )$$

The focal length f of microlens 850a can be configured based on various physical properties of microlens 850a such as, for example, the radius, the height (along the z axis), the curvature, the refractive index of material of microlens 850a, etc. Camera lens 840, microlens 850a, and semiconductor substrate 802 (which can be part of a semiconductor chip) can be mounted in image sensor 600 and separated by spacers to set their relative locations such that exit pupil 902 of camera lens 840 is at the distance u from microlens 850a whereas the semiconductor chip including semiconductor substrate 802 and light receiving surface 806 is at the distance v from microlens 850a. In some examples, the location of light receiving surface 806 of each pixel cell 602 with respect to microlens 850 can be individually adjusted (e.g., via a calibration process) to account for variations in the focal length f of each microlens 850 (e.g., due to variations in the physical properties of each microlens 850.

With such arrangements, light 904 (originated from spot 804a) coming from the left and right of principle axis 908 of microlens 850a can be evenly distributed between the pair of photodiodes on the two sides of principle axis 908, such as between photodiodes 612a and 612b, between photodiodes 612c and 612d, between photodiodes 612a and 612d, and between photodiodes 612b and 612c. Such arrangements can improve the collocated sensing of light 904 by photodiodes 612a-612d of pixel cell 602.

In the example of FIG. 9A, having filter surface 901 at a conjugate position with respect to exit pupil 902 can ensure that crossing point 930, which marks a region where light 904 coming from the left of principle axis 908 (e.g., light 904a) and from the right of principle axis 908 (e.g., light 904b) intercept, is within microlens 850a rather than in filter array 830a. Such arrangements can reduce optical crosstalk between filter elements of filter array 830a. Specifically, light 904a is meant to enter and be filtered by filter element 832b and to be detected by photodiode 612b, whereas light 904b is meant to enter and be filtered by filter element 832a and to be detected by photodiode 612a. By having crossing point 930 above filter array 830a, light 940a can be prevented from entering filter element 832a and leaking into photodiode 612a as optical crosstalk whereas light 940b can be prevented from entering filter element 932b and leaking into photodiode 612b as optical crosstalk. On the other hand, referring to FIG. 9B, if light receiving surface 806 becomes in conjugate with exit pupil 902, crossing point 930 can be pushed into filter array 830a. Light 904a from left of principle axis 908 may enter filter element 832a and leak into photodiode 612a, resulting in optical crosstalk. The arrangements of FIG. 9A can reduce the optical crosstalk.

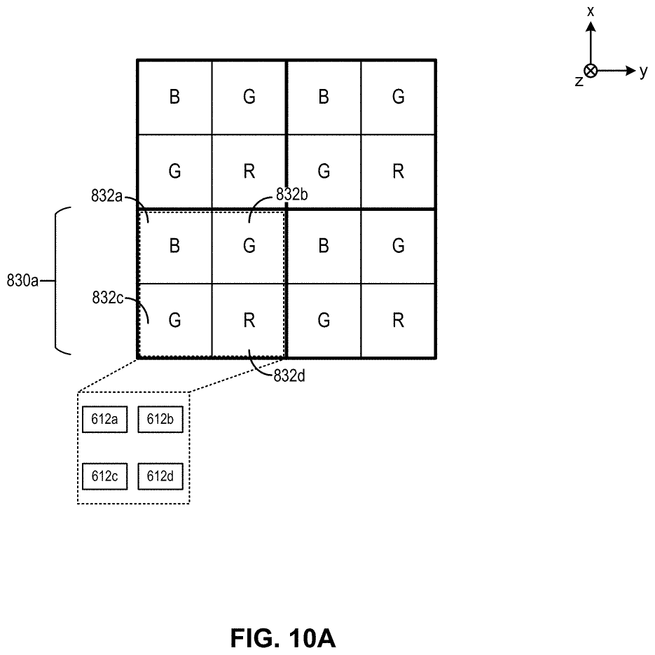

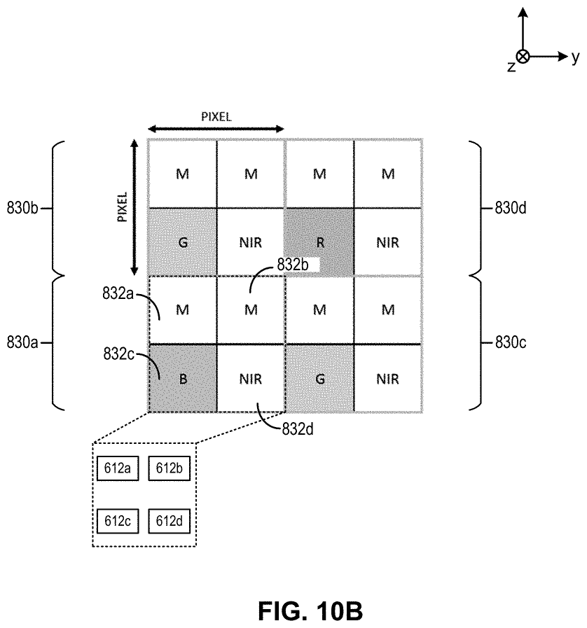

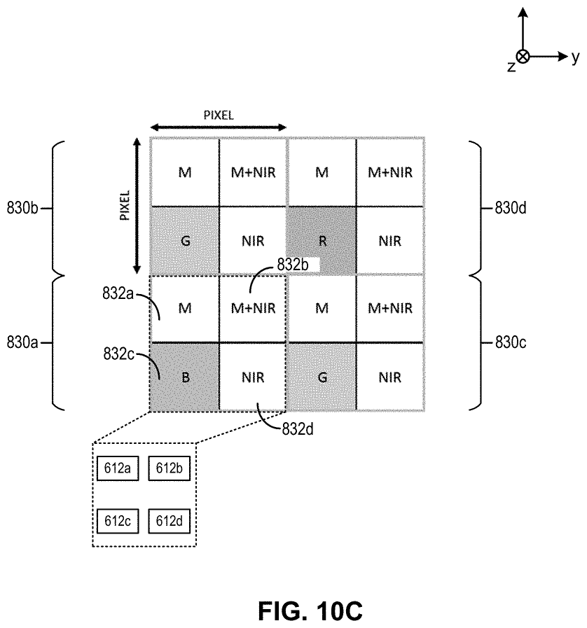

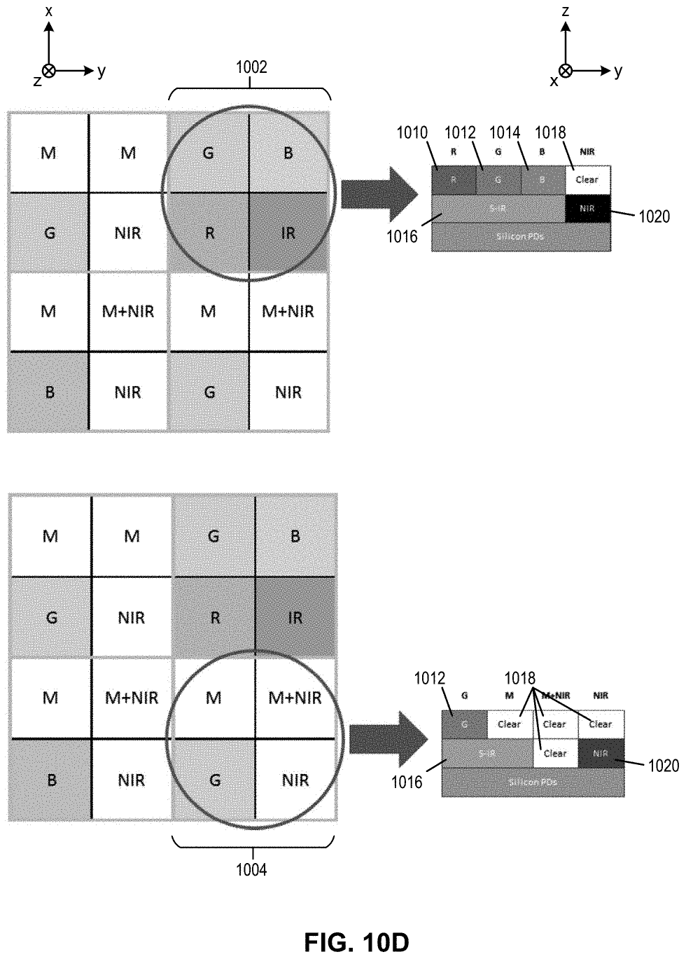

FIG. 10A, FIG. 10B, FIG. 10C, and FIG. 10D illustrate examples of filter arrays 830. In FIG. 10A, each filter array 830 can have a 2×2 configuration based on a Bayer pattern. For example, for filter array 830a, filter element 832a can be configured to pass a blue component of visible light (e.g., within a wavelength range 450-485 nm) to photodiode 612a, filter elements 832b and 832c can be configured to pass a green component of visible light (e.g., within a wavelength range 500-565 nm) to, respectively, photodiodes 612b and 612c, whereas filter element 832d can be configured to pass a red component of visible light (e.g., within a wavelength range 625-740 nm) to photodiode 612d. The arrangements of FIG. 10A can be used in a configuration where the photodiodes of a pixel cell are to perform collocated sensing of different visible components of light from the same spot.

FIG. 10B and FIG. 10C illustrates another example of filter array 830. In FIG. 10B, each of filter arrays 830a, 830b, 830c, and 830d have a filter element 832a and a filter element 832b configured to pass all components of visible light to form a monochrome channel (M), a filter element 832d to pass near infra-red light (e.g., within a wavelength range of 800 to 2500 nm), and a filter element 832c configured to pass a pre-determined component of visible light. For example, for filter array 830a, filter element 832c is configured to pass the blue component of visible light. Moreover, for filter arrays 830c and 830b, filter element 832c is configured to pass the green visible component. Further, for filter array 830b, filter element 832c is configured to pass the red visible component. In FIG. 10C, the filter element 832b of each of filter arrays 830a, 830b, 830c, and 830d can be configured to pass all components of incident light, include visible light and near infra-red light, to form an all-pass channel (M+NIR). In some examples, as shown in FIG. 10B and FIG. 10C, the pre-determined component of visible light passed by filter element 832c of a plurality of filter arrays 830 can follow the aforementioned Bayer pattern. The arrangements of FIG. 10B and FIG. 10C can be used in a configuration where the photodiodes of a pixel cell are to perform collocated sensing of visible components of light and near-infra red component of light from the same spot, to facilitate co-located 2D and 3D imaging.

FIG. 10D illustrates the top view and side view of example filter arrays 1002 and 1004. Filter array 1002 may include a filter element to pass green, blue, and red visible components, as well as an infra-red component. Filter array 1002 can be formed by a stack structure including a red filter element 1010, a green filter element 1012, and a blue filter element 1014 overlaid on an infra-red blocking filter element 1016, such that the photodiodes underneath infra-red blocking filter element 1016 can receive red, green, and blue components of visible light. Moreover, filter array 1002 further include an all-pass filter 1018 (e.g., glass) overlaid on a near infra-red selective filter element 1020 to allow only infra-red component to the photodiode underneath filter element 1020.

Moreover, filter array 1004 may include a filter element to pass green visible light, a filter element to pass monochrome visible light (e.g., all visible light components), a filter element to pass monochrome and infra-red light, and a filter element to pass near infra-red light. Filter array 1004 can be formed by a stack structure including green filter element 1012 and all pass filter 1018 (e.g., glass) overlaid on infra-red blocking filter element 1016 to form the green and monochrome filter elements. Moreover, two all pass filters 1018 can be stacked to pass monochrome and infra-red light, whereas all-pass filter 1018 can be overlaid on near infra-red selective filter element 1020 to allow only infra-red component to go through.

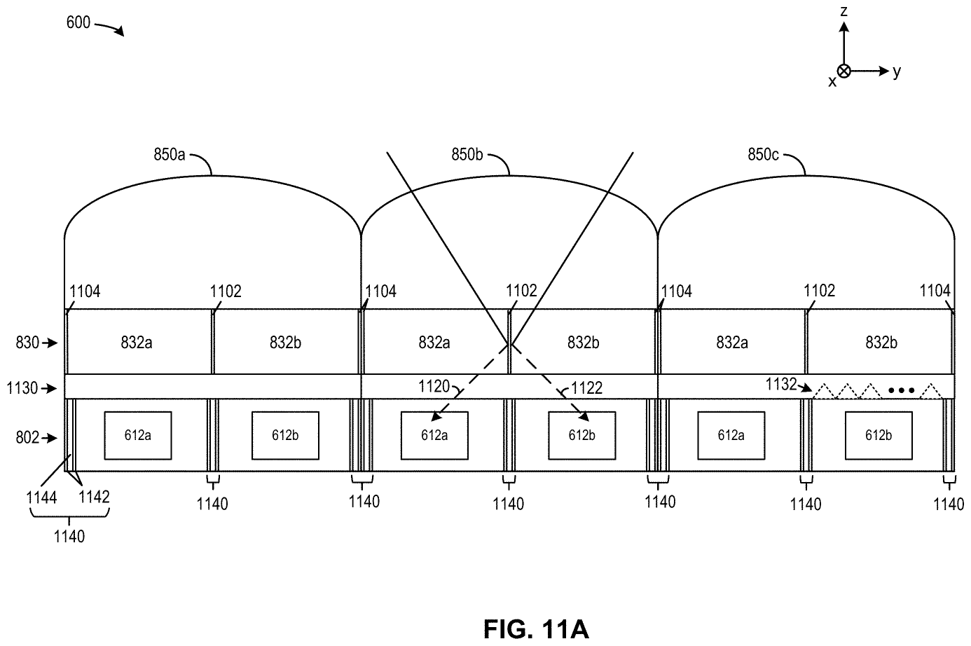

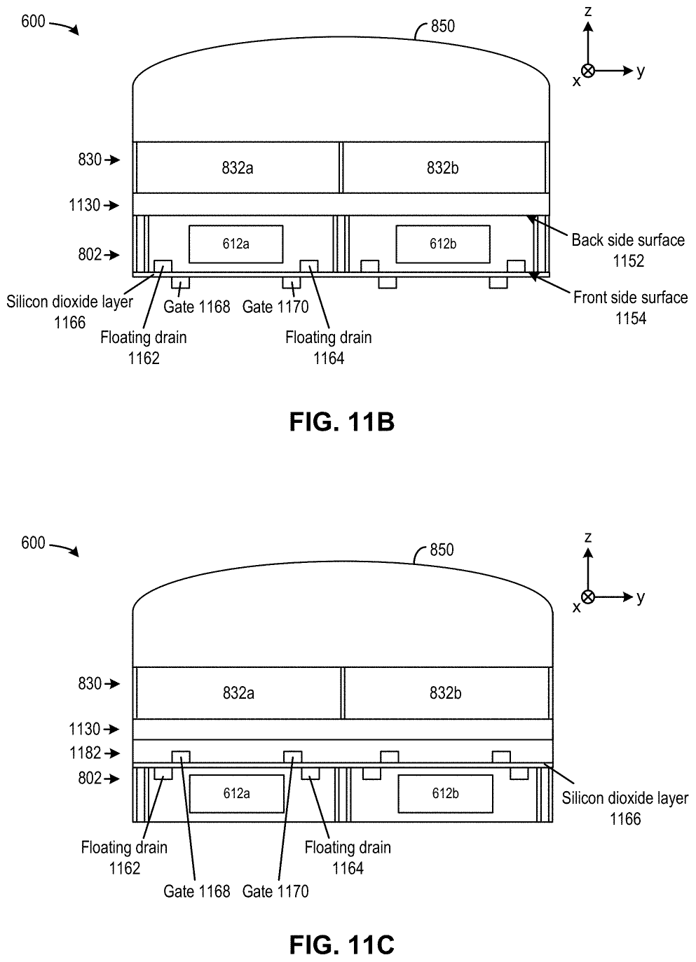

FIG. 11A, FIG. 11B, and FIG. 11C illustrate additional example features of image sensor 600. The additional features can enhance the absorption of light by the photodiodes and/or mitigate the noise component in the charge generated by the photodiodes. Specifically, as shown in FIG. 11A, image sensor 600 may include a separation wall 1102 between adjacent filter elements 832 (e.g., filter elements 832a and 832b) on a pixel cell 602b, as well as a separation wall 1104 between adjacent filter elements on two different pixel cells 602 (e.g., pixel cells 602a and 602b, pixel cells 602b and 602c, etc.). Separation walls 1102 and 1104 can be made of reflective materials, such as metals, and can be configured to guide the filtered light through a filter element into the photodiode below the filter element while preventing the filtered light from entering the adjacent filter element. Such arrangements can reduce optical crosstalk between adjacent filter elements caused by, for example, an out-of-band light component entering a filter element from another filter element. Due to imperfect attenuation/absorption by the filter element, a photodiode may receive the out-of-band light component and convert it into noise charge. For example, in FIG. 11A, filter element 832a of pixel cell 602b is configured to pass the green component of visible light to photodiode 612a to generate filtered light 1120, whereas filter element 832b of pixel cell 602b is configured to pass the blue component of visible light to photodiode 612b to generate filtered light 1122. Without separation wall 1102, filtered light 1122 (which includes the green component), even after attenuation/absorption by filter element 832b, may enter photodiode 612b and converted to charge, which becomes noise charge to the signal charge generated by photodiode 612b in response to the blue component of visible light. Likewise, filtered light 1120 may also enter photodiode 612a and converted to noise charge in addition to the signal charge generated by photodiode 612a in response to the green component of visible light. On the other hand, with separation wall 1102, filtered light 1120 can be reflected and guided towards photodiode 612a, whereas filtered light 1122 can be reflected and guided towards photodiode 612b. Such arrangements not only can enhance the absorption of out-of-band light components by each filter element but also prevent out-of-band light components from reaching the photodiodes, which can reduce optical crosstalk and the resulting noise charge.

In addition, an optical layer 1130 can be interposed between filter array 830 and semiconductor substrate 802. Optical layer 1130 can be configured to enhance the absorption of the filtered light (e.g., filtered light 1120 and 1122) by the photodiodes 612 of semiconductor substrate 802. In some examples, optical layer 1130 can be configured as an anti-reflection film to prevent (or reduce) the reflection of filtered light away from semiconductor substrate 802 back into filter array 830. The anti-reflection film can employ various techniques to reduce reflection, such as refractive index matching, interference, etc. In some examples, optical layer 1130 may also include micro-pyramid structures 1132 embedded in a thin film. Micro-pyramid structures 1140 can act as a waveguide to guide the filtered light, such as infra-red light, towards photodiodes 612.

Furthermore, semiconductor substrate 802 may include isolation structures 1140 between adjacent photodiodes 612. Isolation structures 1140 can be configured to provide electrical isolation between adjacent photodiodes 612, to prevent a charge generated by one photodiode from entering another photodiode, which would become a noise charge. In some examples, isolation structures 1140 can be implemented as deep trench isolation (DTI) structures including sidewalls 1142 and filling 1144. Sidewalls 1142 are typically implemented based on an insulator material, such as silicon dioxide, to provide the electrical isolation. Filling 1144 can be a conductive material to allow the DTI structures to conduct an electrical potential, which can cause charge to accumulate at the interface between silicon semiconductor substrate 802 and the silicon dioxide sidewalls 1142, which can reduce dark charge generation at the crystal defects at the interface. In some examples, filling 1144 can be metal, which can reflect and guide filtered light through the photodiode. Such arrangements not only can enhance absorption of the filtered light by the photodiode but also can prevent the filtered light from entering an adjacent photodiode to prevent optical crosstalk, similar to separation walls 1102 and 1104. In addition, photodiodes 612 can be configured as pinned photodiodes such that the charge generation region of each photodiode is isolated within semiconductor substrate 802, which can further suppress the effect of dark charge on the photodiodes.

FIG. 11B and FIG. 11C illustrate different example configurations of image sensor 600. In FIG. 11B, image sensor 600 is configured as a back side illuminated (BSI) device, in which back side surface 1152 of semiconductor substrate 802 is configured as light receiving surface 806. On the other hand, in FIG. 11C, image sensor 600 is configured as a front side illuminated (FSI) device, in which front side surface 1154 of semiconductor substrate 802 is configured as light receiving surface 806. In semiconductor substrate 802, the front side surface can be the surface where various semiconductor processing operations, such as ion implantation, silicon deposition, etc., take place, whereas the back side surface is opposite to front side surface. In both FIG. 11B and FIG. 11C, image sensor 600 further includes floating drains 1162 and 1164 formed under front side surface 1154, a silicon dioxide layer 1166 formed on front side surface 1154, and polysilicon gates 1168 and 1170 formed on silicon dioxide layer 1166. Floating drains 1162 and 1164 can be configured as part of the charge storage device of charge sensing unit 614 to convert the charge generated by a photodiode 612 to a voltage, whereas polysilicon gates 1168 and 1170 can control the flow of charge from photodiode 612 to, respectively, floating drains 1162 and 1164. Floating drains 1162 and 1164, as well as photodiode 612, can be formed via an ion implantation process on front side surface 1154, whereas polysilicon gates 1168 and 1170 can be formed via a silicon deposition process on front side surface 1154. In some examples, as shown in FIG. 11C, image sensor 600 further includes an insulator layer 1182 (which can be silicon dioxide) to act as a spacer to separate and insulate polysilicon gates 1118 and 1120 from optical layer 1130.

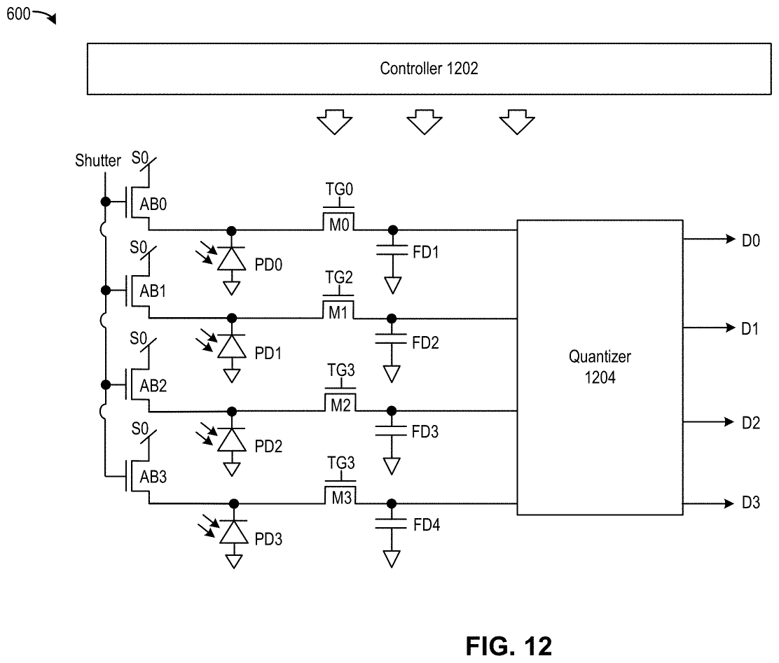

FIG. 12 illustrates a circuit schematic of image sensor 600 including pixel cell 602a, a controller 1202 and a quantizer 1204. Pixel cell 602a includes photodiodes PD0, PD1, PD2, and PD3, which can represent, respectively, photodiodes 612a, 612b, 612c, and 612d in FIG. 6. Moreover, pixel cell 602a further includes transfer gates M1, M2, M3, and M4 which can represent polysilicon gates 1168 and 1170 of FIG. 11B and FIG. 11C. Pixel cell 602a further includes floating drains FD1, FD2, FD3, and FD4, which can represent floating drains 1162 and 1164 of FIG. 11B and FIG. 11C. Pixel cell 602a also includes shutter gates AB0, AB1, AB2, and AB3. The shutter gates can control the start of the exposure period for each of photodiodes PD0, PD1, PD2, and PD3. In some examples, each photodiode of pixel cell 602a can have the same global exposure period, with the shutter gates controlled by the same shutter signal, such that the exposure period for each photodiode starts and ends at the same time. Before the exposure period starts, the shutter gates are enabled to steer the charge generated by the photodiodes to a current sink S0. After the exposure period starts, the shutter gates are disabled, which allow each photodiode to generate and accumulate a charge based on detecting light component of a pre-determined wavelength range set by its corresponding filter element 832. The light components can be from the same spot of a scene and projected by a microlens 850a overlaid on pixel cell 602a. Before the exposure period ends, the transfer gates M0, M1, M2, and M3 can be enabled by, respectively, control signals TG0, TG1, TG2, and TG3 to transfer the charge generated by each photodiode PD0, PD1, PD2, and PD3 to the respective floating drains FD0, FD1, FD2, and FD3 to convert to voltages V0, V1, V2, and V3. Quantizer 1204 can quantize the voltages to digital values D0, D1, D2, and D3, each can represent the same pixel in different 2D and 3D image frames. The control signals AB0-AB3, TG0-TG3, as well as the quantization operations by quantizer 1204 can be controlled by controller 1202.

The foregoing description of the embodiments of the disclosure has been presented for the purpose of illustration; it is not intended to be exhaustive or to limit the disclosure to the precise forms disclosed. Persons skilled in the relevant art can appreciate that many modifications and variations are possible in light of the above disclosure.

Some portions of this description describe the embodiments of the disclosure in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, and/or hardware.

Steps, operations, or processes described may be performed or implemented with one or more hardware or software modules, alone or in combination with other devices. In some embodiments, a software module is implemented with a computer program product comprising a computer-readable medium containing computer program code, which can be executed by a computer processor for performing any or all of the steps, operations, or processes described.

Embodiments of the disclosure may also relate to an apparatus for performing the operations described. The apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments of the disclosure may also relate to a product that is produced by a computing process described herein. Such a product may comprise information resulting from a computing process, where the information is stored on a non-transitory, tangible computer readable storage medium and may include any embodiment of a computer program product or other data combination described herein.

The language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the disclosure, which is set forth in the following claims.

What is claimed is:

1. An apparatus comprising:
a semiconductor substrate including a plurality of pixel cells, each pixel cell including at least a first photodiode, a second photodiode, a third photodiode, and a fourth photodiode
a plurality of filter arrays, each filter array including at least a first filter element, a second filter element, a third filter element, and a fourth filter element, the first filter element of the each filter array overlaid on the first photodiode of the each pixel cell, the second filter element of the filter array overlaid on the second photodiode of the each pixel cell, the third filter element of the filter array overlaid on the third photodiode of the each pixel cell, the fourth filter element of the filter array overlaid on the fourth photodiode of the each pixel cell, at least two of the first, second, third, and fourth filter element of the each filter array having different wavelength passbands; and
a plurality of microlens, each microlens overlaid on the each filter array and configured to direct light from a spot of a scene via the first filter element, the second filter element, the third filter element, and the fourth filter element of the each filter array to, respectively, the first photodiode, the second photodiode, the third photodiode, and the fourth photodiode of the each pixel cell.

2. The apparatus of claim 1, wherein:
the first filter element and the second filter element of the each filter array are aligned along a first axis;
the first photodiode and the second photodiode of the each pixel cell are aligned along the first axis underneath a light receiving surface of the semiconductor substrate; and
the first filter element is overlaid on the first photodiode along a second axis perpendicular to the first axis;
the second filter element is overlaid on the second photodiode along the second axis; and
the each microlens is overlaid on the first filter element and the second filter element of the each filter array along the second axis.

3. The apparatus of claim 2, further comprising a camera lens overlaid on the plurality of microlenses along the second axis,
wherein a surface of the each filter array facing the camera lens and an exit pupil of the camera lens are positioned at conjugate positions of the each microlens.

4. The apparatus of claim 1, wherein the first filter element and the second filter element overlaid on the each pixel cell are configured to pass different color components of visible light to, respectively, the first photodiode and the second photodiode of the each pixel cell.

5. The apparatus of claim 4, wherein the first filter element and the second filter element of each filter array are arranged based on a Bayer pattern.

6. The apparatus of claim 1, wherein the first filter element is configured to pass one or more color components of visible light; and
wherein the second filter element is configured to pass an infra-red light.

7. The apparatus of claim 1, wherein the first filter elements of the plurality of filter arrays are arranged based on a Bayer pattern.

8. The apparatus of claim 1, wherein the first filter element comprises a first filter and a second filter forming a stack along the second axis.

9. The apparatus of claim 1, further comprising a separation wall between adjacent filter elements overlaid on a pixel cell and between adjacent filter elements overlaid on adjacent pixel cells.

10. The apparatus of claim 9, wherein the separation wall is configured to reflect light that enters a filter element of the each filter array from the each microlens towards the photodiode on which the filter element is overlaid.

11. The apparatus of claim 10, wherein the separation wall includes a metallic material.

12. The apparatus of claim 1, further comprising an optical layer interposed between the plurality of filter arrays and the semiconductor substrate;
wherein the optical layer includes at least one of: an anti-reflection layer, or a pattern of micro-pyramids configured to direct infra-red light to at least one of the first photodiode or the second photodiode.

13. The apparatus of claim 1, further comprising an isolation structure interposed between adjacent photodiodes of the each pixel cell and adjacent photodiodes of adjacent pixel cells.

14. The apparatus of claim 13, wherein the isolation structure comprises a deep trench isolation (DTI), the DTI comprising insulator layers and a metallic filling layer sandwiched between the insulator layers.

15. The apparatus of claim 1, wherein the first photodiode and the second photodiode of the each pixel cell are pinned photodiodes.

16. The apparatus of claim 1, wherein a back side surface of the semiconductor substrate is configured as a light receiving surface from which the first photodiode and the second photodiode of the each pixel cell receive light;
wherein the semiconductor further comprises, in the each pixel cell, floating drains configured to store charge generated by the first photodiode and the second photodiode of the each pixel cell; and
wherein the apparatus further comprises polysilicon gates formed on a front side surface of the semiconductor substrate opposite to the back side surface to control flow of the charge from the first photodiode and the second photodiode to the floating drains of the each pixel cell.

17. The apparatus of claim 1, wherein a front side surface of the semiconductor substrate is configured as a light receiving surface from which the first photodiode and the second photodiode of the each pixel cell receive light;
wherein the semiconductor further comprises, in the each pixel cell, floating drains configured to store charge generated by the first photodiode and the second photodiode of the each pixel cell; and
wherein the apparatus further comprises polysilicon gates formed on the front side surface of the semiconductor substrate to control flow of the charge from the first photodiode and the second photodiode to the floating drains of the each pixel cell.

18. The apparatus of claim 1, wherein the semiconductor substrate is a first semiconductor substrate;
wherein the apparatus further comprises a second semiconductor substrate comprising a quantizer to quantize charge generated by the first photodiode and the second photodiode of the each pixel cell; and
wherein the first semiconductor substrate and the second semiconductor substrate form a stack.

19. The apparatus of claim 18, wherein the second semiconductor substrate further includes an imaging module configured to:
generate a first image based on the quantized charge of the first photodiode of the each pixel cell; and
generate a second image based on the quantized charge of the second photodiode of the each pixel cell; and
wherein each pixel of the first image corresponds to each pixel of the second image.

20. The apparatus of claim 19, wherein each pixel of the first image and each pixel of the second image are generated based on charge generated by the first photodiode and the second photodiode within an exposure period.
